(19) United States
(12) Patent Application Publication
(10) Pub. No.: US 2007/0103980 A1
(43) Pub. Date: May 10, 2007

(54) Method for operating a semiconductor memory device and semiconductor memory device

(76) Inventors: Gert Koebernick, Dresden (DE); Uwe Augustin, Dresden (DE)

Correspondence Address: SLATER & MATSIL LLP, 17950 PRESTON ROAD, SUITE 1000, DALLAS, TX, 75252, US

(21) Appl. No.: 11/272,044

(22) Filed: Nov. 10, 2005

(51) Int. Cl. G11C 16/06

(52) U.S. Cl. 365/185.09

(57) ABSTRACT

A method for restoring information stored in a memory cell that has a variable characteristic indicating the stored information, wherein a first state is stored if the characteristic is below a reading threshold or a second state is stored if the characteristic is above the reading threshold. The method includes verifying whether the absolute value of a first difference between the characteristic and the reading threshold is larger than a given first threshold. If the absolute value of the first difference is larger than the given first threshold, the method further includes changing the characteristic so that the absolute value of the first threshold is reduced or that the stored state is altered.

### TECHNICAL FIELD

The present invention generally relates to a semiconductor memory device comprising a plurality of memory cells and more particularly relates to a method for operating a semiconductor memory device in order to prepare the memory cells for restoring.

### BACKGROUND

Portable devices such as digital cameras and music players comprise non-volatile memory units. These portable devices have become smaller in recent years, as have the respective memory units. It is assumed that the miniaturization of portable devices will proceed. In order to fulfill the need for improved performance the amount of data that can be stored in the non-volatile memory unit may increase. As a result, for example more music, photos or other data can be stored in smaller devices.

Non-volatile memory units may be designed in the form of electrical erasable programmable read only memory (EEPROM), which can be electrically programmed and electrically erased. The EEPROM retains stored data for a long time without power supply and can be programmed and erased many times.

The EEPROM memory unit comprises a plurality of memory cells each enabled to store a small piece of information. Memory cells may enable to store only one bit. Multi-bit memory cells, however, can store more than one bit. A so-called nitride programmable read only memory cell (NROM cell) is operable to store two bits. The NROM cell is described in U.S. Pat. No. 6,011,725.

An embodiment of the NROM memory cell comprises a transistor body including a cell well having a first and a second doping area. A channel region is located between the first and the second doping area. A gate electrode is arranged above the channel region insulated by a dielectric layer, which is arranged between the channel region and the gate electrode. The dielectric layer comprises a top oxide layer, a nitride layer, e.g. silicon nitride, and a bottom oxide layer. The nitride layer serves as a charge-trapping layer sandwiched between the insulating oxide layers, which avoid vertical retention. Alternative materials for forming the charge-trapping layer are also possible.

Two individual bits can be stored in different regions of the nitride layer. A first bit region is located adjacent to the first doping area and a second bit region is located adjacent to the second doping area.

The bits are programmed by means of channel hot electron programming. Electrons are injected from the channel region into the charge-trapping layer. Programming of the first bit is performed by applying programming potentials to the first doping area and to the gate while grounding the second doping area. Typically the programming potential of about 9 V is applied to the gate and the programming potential of about 4.5 V is applied to the first doping area. Due to the resulting field, electrons are injected and trapped into the first bit region, which is adjacent to the first doping area. Likewise programming of a second bit is performed by applying the programming potentials to the second doping area and to the gate while grounding the first doping area. In this case the electrons are injected and trapped into the second bit region. Typically the programming potentials are applied in such a way that the resulting field is impressed in pulses.

For erasing an injection of hot holes, Fowler-Nordheim tunnelling can be used. Erasing of the first bit is performed by applying erasing potentials to the gate or to the first doping area and the gate. Typically about 6 V are applied to the first doping area and a negative voltage related to ground of about −7 V is applied to the gate. The applied erasing potentials result in an electrical field. Holes are caused to overcome the bottom oxide layer for compensating the charges of the trapped electrons. The second bit is erased by applying the erasing potentials to the gate and to the second doping area. Alternatively, erasing of the first and second bit may be performed by applying a negative voltage related to ground only to the gate.

The bit is read by applying a reverse voltage between the first and second doping area compared to the programming voltage that is used to program this bit. Typically a reading potential of 1.5 V is applied to the second doping area while grounding the first doping area in order to read the first bit. A current flows while there are no, or nearly no, trapped electrons inside the first bit region. Relatively small charges near the first doping area reduce the current flow. Reading the second bit is performed by applying the reading potential to the first doping area while grounding the second one. During performing the reading step a voltage of typically 4V is applied to the gate.

A memory cell array includes a plurality of memory cells arranged as a matrix having rows and columns. The memory cell array includes a plurality of wordlines and a plurality of bitlines. One of the pluralities of wordlines connects the gate electrodes that are arranged in a same row. Thus, a potential applied to the wordline is applied to the gate electrode of each memory cell arranged in the same row. Each bitline forms the first doping areas of the memory cells which are arranged in a same column located on one side of the bitline and forms the second doping areas of the memory cells which are arranged in a same column located on the other side of the bitline. A potential that is applied to one of the bitlines is coupled to the memory cells located on either side of this bitline.

Each memory cell can be identified by the wordline and the bitlines on either side that are coupled to that memory cell. Programming, erasing or reading of one of the memory cells is performed by applying the programming potentials, erasing potentials or reading potentials, respectively, to the wordline and the bitlines connected to that memory cell.

The bitlines may be coupled to a bitline decoder. The wordlines may be coupled to a wordline decoder. The bitline decoder is operable to apply the programming, reading or erasing potentials to each bitline, in particular to a pair of adjacent bitlines in order to program, read or erase the bits stored in the memory cell coupled between these two bitlines. The wordline decoder is operable to apply the programming or erasing potential to each of the wordlines. The bitline decoder and the wordline decoder are coupled to an address decoder which is operable to identify the memory cells storing bits to be programmed, erased or read. The address decoder is further operable to control the bitline decoder and the wordline decoder in order to perform access to these memory cells.

Altering the information stored in the memory cells of the memory cell array may be performed by erasing all bits stored in the memory cells and then programming selected bits in order to store the altered information.

Each memory cell may be assigned to one of a plurality of erasing sectors, which includes a group of wordlines and a group of bitlines. Each memory cell assigned the erasing sector is coupled to one of the group of wordlines and between two adjacent bitlines of the group of bitlines. Typically the memory cells of a flash memory cell array are erased synchronously by erasing sector by sector. The erasing potentials may be applied to the group of wordlines and the odd-numbered bitlines of the group of bitlines in order to erase one bit of the two bits stored in each memory cell assigned to the erasing sector. Then the erasing potentials may be applied to the group of wordlines and the even-numbered bitlines of the group of bitlines in order to erase the other bits stored in each memory cell.

The programmed bits and the erased bits are erased by these proceedings. Holes are forced to be trapped into the charge trapping regions of the memory cells. If the bit is programmed, the holes neutralize the electrons trapped within the charge-trapping region in order to erase the respective bit. If the bit is already erased, the injection of the holes may result in a so-called over-erased bit due to further decreasing of the threshold voltage. The threshold voltage representing the over-erased bit is significantly decreased compared to the average threshold voltage of erased bits. In particular, if the bit is rarely programmed and often erased on a series the bit may become over-erased. Memory cells storing over-erased bits may cause leakage currents in the array due to failures during sensing other bits on the same bitline.

### SUMMARY OF THE INVENTION

The present invention discloses a method of and an apparatus for restoring, and more particularly for preparing for restoring, information stored in a memory cell. The flash memory cell has a variable characteristic indicating whether a first or second state is stored. The first state is stored if the characteristic is below a reading threshold. The second state is stored if the characteristic is above the reading threshold.

Preferably, the characteristic includes a threshold voltage of the memory cell. Each bit is indicated by one threshold voltage.

The method comprises verifying whether the absolute value of a first difference between the characteristic and the reading threshold is larger than a given first threshold value. If the absolute value of the first difference is larger than the given first threshold value, the characteristic is changed and the characteristic is closer to the reading threshold or the stored state is altered. In case of verifying erased bits, the method comprises verifying whether the threshold voltage is less than a given first threshold voltage.

Advantageously, the characteristic changed in the previous step is verified whether the absolute value of a second difference between the characteristic and the reading threshold is larger than a given second threshold value. In this case, the characteristic already changed in the previous step is changed again, and it is closer to the reading threshold, or the stored state is altered.

A preferred aspect of this method is the threshold voltages of the over-erased bit are modified in order to mitigate the degrading effects of a following erasing step.

During the second changing step preferably only the characteristics are changed again, which were hard to change during the first changing step. Although these characteristics are hard to change during the changing step, which prepares the restoring step, they are significantly varied during the re-storing step. The differences of these characteristics to the reading thresholds are significantly increased by performing and restoring, which may result in further over-erasing of the bit. In order to mitigate this degrading effect the characteristics that are hard to change are changed again.

The stored information can be restored by applying a sequence of storing pulses to the respective memory cell.

The stored information is preferably altered by applying a sequence of altering pulses to the respective memory cell. In and embodiment, changing is performed by applying a few, in particular only one, altering pulse to the memory cell. If the method is applied to erased bits the changing step comprises applying at least one programming pulse to the memory cell storing the over-erased bit.

Performing two steps in order to verify to the first and the second threshold, respectively, each followed by a changing step is more preferred than performing only one step in order to verify to the second threshold followed by the changing step. In an embodiment comprising performing two changing steps, each changing step comprises applying one changing pulse. During the second step the changing pulse is only applied in order to change bits that are hard to change. Thus, a total of two changing pulses are applied in order to change these bits. In case of performing only one changing step, two changing pulses have to be applied to each memory cell storing an over-erased bit in order to assure that even the characteristics that are hard to change will be changed. This proceeding requires more energy for applying an increased number of changing pulses compared to the method that includes two verifying steps.

After performing the verifying and changing steps the memory cell may be tuned in such a manner that after performing the erasing step the bit will not become over-erased again but rather will be represented by a characteristic, which is in the range of the average characteristics of the erased bits.

The verifying and changing step may be repeated several times wherein the second threshold may be changed each time. The second threshold may come closer to the reading threshold step by step in order to adjust the tuning effect.

Embodiments are not limited to performing the above-mentioned preparing proceedings prior to each erasing step. They may be performed merely after performing several erasing steps without prior preparing. Alternatively in other embodiments, only a group of the erasing sectors is prepared prior to erasing.

Embodiments may also comprise preparing only memory cells that have been erased several times in series. If pattern scrambling is used, only a few bits are still erased in series so that the effort of preparing is further reduced.

Embodiments of the invention also provide an apparatus for preparing the memory cells. In an embodiment, the apparatus for preparing the memory cells comprises a memory cell array having a plurality of memory cells. Each memory cell is operable to store information. Furthermore each memory cell has a characteristic indicating the stored information.

Embodiments may further comprise a verifying unit. The verifying unit is coupled to the memory cell array being operable to verify whether the absolute value of a difference between the characteristic and the reading threshold is larger than a given threshold. The threshold includes the first or the second threshold. The second threshold may be variable in order to perform the preparing proceeding with several verifying and changing steps.

Embodiments may further comprise an access unit coupled to the memory cell array and/or the verifying unit. The access unit is preferably operable to store the information into each memory cell. The access unit is preferably further operable to alter the stored information and to change the characteristic of the memory cells that the characteristic is closer to the reading threshold or that the stored state is altered, if the absolute value of the difference is larger than the given threshold. Furthermore the access unit is operable to change the characteristics assigned to the first group. The access unit is also operable to identify memory cells having a characteristic assigned to the first group.

In an embodiment, an assigning unit is operable to assign the characteristic the absolute value of the difference when the reading threshold is larger than the given threshold to the first group.

The access unit is preferably operable to provide storing pulses in order to erase a bit, and altering pulses in order to program the erased bit. The erased bit is programmed by applying a sequence of altering pulses. The access unit is further operable to provide a changing signal in order to change the characteristics. The changing signal may comprise only one or a few altering pulses. Alternatively the changing signal may comprise pulses having a larger, or less voltage, than the voltage of one of the altering pulses. Such changing pulses change the characteristic more or less, respectively, significantly than the altering pulse.

### BRIEF DESCRIPTION OF THE DRAWINGS

For a more complete understanding of the present invention and its advantages, reference is now made to the following description taken in conjunction with the accompanying drawings in which:

FIG. 1 shows a cross-section of an NROM memory cell;

FIG. 2 shows a block diagram of an NROM memory cell array;

FIG. 3 shows a histogram of the threshold voltages of bits stored in the memory cell array;

FIG. 4 shows the distribution of the threshold voltages of the bits stored in the memory cell array after verifying to a first threshold;

FIG. 5 shows the histogram according to FIG. 4 after changing the threshold voltages;

FIG. 6 shows the histogram according to FIG. 5 after verifying and changing the threshold voltages again;

FIG. 7 shows a flow chart of a first embodiment of the inventive method;

FIG. 8 shows a flow chart of a second embodiment of the inventive method;

FIG. 9 shows a flow chart of a third embodiment of the inventive method;

FIG. 10 shows a flow chart of a fourth embodiment of the inventive method;

FIG. 11 shows a first embodiment of a memory device; and

FIG. 12 shows a second embodiment of a memory device.

The following list of reference symbols can be used in conjunction with the figures:

| | | | |
|---|---|---|---|
| 1 | Memory cell array | 51 | First distribution curve |
| 2 | Verifying unit | 50 | Second distribution curve |
| 3 | Access unit | 31 | Erasing range |
| 4 | Assigning unit | 30 | Programming range |
| 10 | Erasing sector | 500 | Right tale of second distribution curve |
| 20 | Bitline | 501 | Left tale of second distribution curve |
| 40 | Wordline | 510 | Right tale of first distribution curve |
| 100 | Memory cell | 511 | Left tale of first distribution curve |
| 101 | First bit | 61, 61b | First group |
| 102 | Second bit | 62, 61a | Second group |
| 201 | First doping area | VT | Threshold voltage |
| 202 | Second doping area | EV | Erase voltage |
| 250 | Substrate | PV | Program voltage |
| 251, 252, 253 | Oxide-nitride-oxide layer | P1, P2 | Average threshold voltage |
| 254 | Channel region | PAEV | Leakage threshold voltage |
| 255 | Cell well | PBE_RD | First threshold voltage |
| 400 | Gate | EV2 | Second threshold voltage |

### DETAILED DESCRIPTION OF ILLUSTRATIVE EMBODIMENTS

Preferred embodiments are discussed in detail below. It should be noted that the present invention provides many applicable concepts that can be embodied in a wide variety of specific contexts. The specific embodiments discussed are merely illustrative of specific ways to make and use the invention and do not limit the scope of the invention.

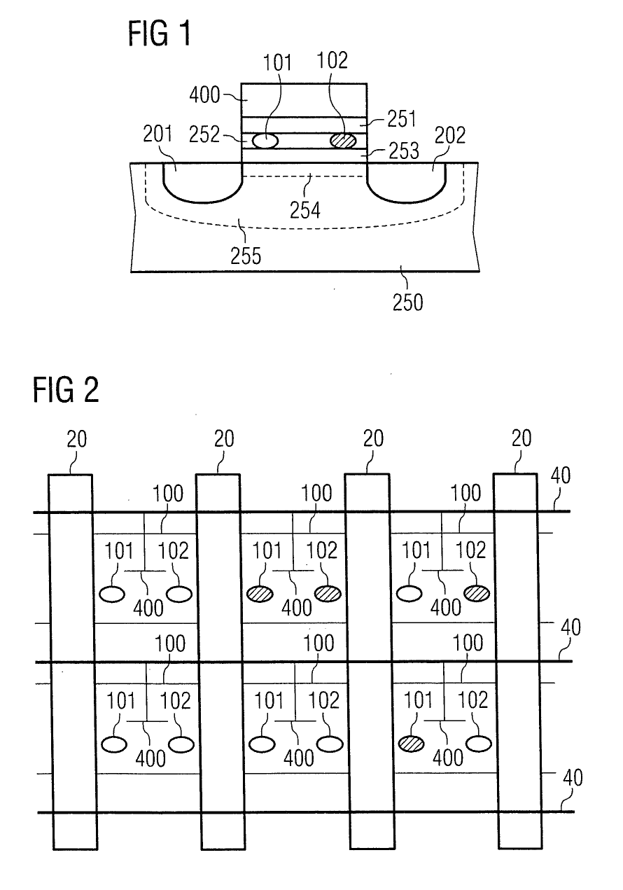

FIG. 1 shows an embodiment of an NROM memory cell. The memory cell comprises a transistor body including a cell well 255 which has a first doping area 201 and a second doping area 202. A channel region 254 is located between the first and the second doping areas 201, 202. A gate electrode 400 is arranged above the channel region 254 and is insulated by an oxide-nitride-oxide layer 251, 252, 253, wherein the nitride layer 252 serves as a charge-trapping layer.

A first bit 101 and a second bit 102 can be stored within different areas of the charge-trapping nitride layer 252. The first bit 101 is stored in a first bit region located near the first doping area 201 and the second bit 102 is stored in a second bit region located near the second doping area 202. If a certain amount of charges is trapped in one of these bit regions the respective bit is called “programmed” representing a logical 0. If less than the certain amount of charges, or no charge, is trapped within one of these bit regions, the respective bit is called “erased” representing a logical 1.

The first and the second bit are indicated in FIG. 1 by two ellipses 101, 102. An empty ellipse represents the erased bit and a hatched circle represents the programmed bit.

The first and the second bit 101, 102 affect a first threshold voltage and a second threshold voltage, respectively. The threshold voltage depends on the amount of charges trapped in the respective bit region.

The first bit 101 stored in the memory cell 100 is read by applying a reading voltage between the second and the first doping area 202, 201. If the first bit is programmed, a current does not flow between the first and second doping area 201, 202 because the first threshold voltage is larger than the reading voltage. If the first bit is erased, the current flows because the first threshold voltage is less than the reading voltage. The first threshold voltage increases with the increasing amount of charges trapped inside the first bit region.

The second bit 102 of the memory cell 100 is read by applying the reading voltage between the first and the second doping area, 201, 202. If the second bit 102 is programmed, the second threshold voltage indicating the binary value of the second bit 102 is larger than the reading voltage, so that the current does not flow or flow to a particular magnitude. If the second bit 102 is erased, the second threshold voltage is less than the reading voltage, so that the current flows. The second threshold voltage increases the increasing amount of charges trapped inside the second bit region.

FIG. 2 shows a block diagram of a memory cell array that comprises a plurality of memory cells 100. The memory cells 100 are arranged in rows and columns. The gate electrode 400 of each memory cell 100 arranged in and same one of the plurality of the rows is connected to a same one of the plurality of wordlines 40. The first doping area of the memory cells 100, which are arranged in a same column, are formed by a same one of the plurality of bitlines 20. The same bitline 20 forms the second doping areas of the memory cells 100, which are arranged in the adjacent column.

The memory content of memory cells 100 may be changed by first erasing the memory cells 100 simultaneously or stepwise. Then selected first bits 101 and selected second bits 102 are programmed depending upon the information that is to be stored in the memory cells 100.

Erasing is performed by applying an erasing potential, which is a high negative voltage relative to ground, to the wordlines 40. Alternatively it is possible to apply erasing potentials to the bitlines 20 as well. Usually erasing is performed block wise. The erasing potential is applied to all memory cells of one erasing sector, which may comprise erased and programmed bits. The resulting electrical field causes holes to inject from the channel region 254 into the charge-trapping region 252. Thus erased bits are re-erased during the erasing step.

If a programmed bit is erased, the injected holes neutralize the electrons which are trapped in the charge trapping region. Thus the threshold voltage indicating the bit is decreased and the threshold voltage is less than the reading voltage.

If the erasing potential is applied to an erased bit, the holes are also injected into the respective bit region. These holes cannot be neutralized because there are no or only few electrons, trapped in the bit region. The threshold voltage representing the erased bit may be further decreased.

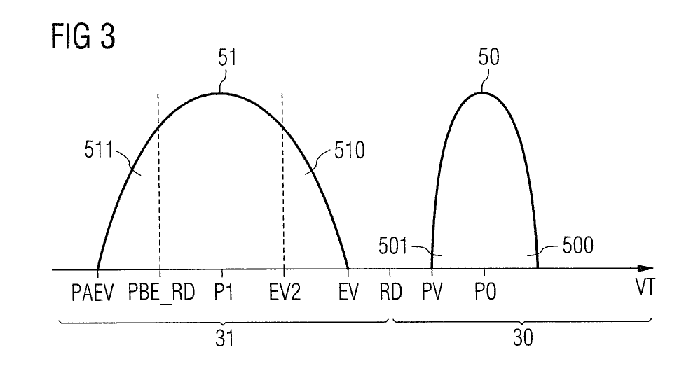

FIG. 3 shows a typical distribution of the first and second threshold voltages VT of a plurality of first and second bits 101, 102 stored in a memory cell array. The stored bits 101, 102 are either programmed or erased.

The distribution comprises two bell shaped distribution curves 50, 51 within a programming range 30 above the reading voltage RD and within an erasing range 31 below the reading voltage RD, respectively. The first curve 51 indicates the distribution of erased bits over the threshold voltage VT. These bits are represented by threshold voltages VT, which are less than the reading voltage RD and usually less than an erase voltage EV. The second curve 50 indicates the distribution of the programmed bits represented by threshold voltages VT being larger than the reading voltage RD and usually larger than a program voltage PV.

Bits within the left tail 511 of the first curve 51 are called over-erased. Their threshold voltages VT are well below an average threshold voltage P1 of the erased bits. Bits within the right tail 510 of the first curve 51 are called under-erased. Their threshold voltages VT are well above an average threshold voltage P1 of the erased bits.

Likewise the bits within the left tail 501 of the second curve 50 are called under-programmed and bits within the right tail 500 of the second curve 50 are called over-programmed.

The step of erasing one of the programmed bits includes changing the threshold voltage VT that represents the bit from the programming area 30 into the erasing range 31. Erasing is performed by applying the erasing potentials in pulses to the memory cell that stores the bit. In preferred embodiments, the number of erasing pulses that are applied to each memory cell is fixed and does not vary from memory cell to memory cell.

In consequence of each erasing pulse a quantum of holes is injected into the respective bit regions of the memory cells. The amount of this quantum may vary from memory cell to memory cell. Likewise differences between the threshold voltages of each bit being erasing and the same bit being programmed may differ from bit to bit. The mean difference between the threshold voltage of the programmed bits and the threshold voltage of the same bits after erasing is about the difference between the average threshold voltages P1 and P0. However, after performing erasing over-programmed bits and under-programmed bits mostly become under-erased bits and over-erased bits, respectively.

Usually erasing is performed by applying the erasing pulses to all memory cells of a sector. Thus the threshold voltages of the programmed bits are significantly decreased in order to erase the bits and the threshold voltages of the erased bits are further decreased. The threshold voltage decrease of the erased bits is less than the threshold voltage decrease of the programmed bits. Contrary to erasing, programming comprises applying the programming pulses to selective memory cells that are to be programmed.

An over-programmed bit may be hard to erase because the representing threshold voltage VT has to be decreased by at least the difference between the threshold voltage VT and the reading voltage RD. A bit that is hard to erase becomes under-programmed after performing erasing. This bit is usually easy to program because the difference between the threshold voltage VT of the erased bit and the reading voltage RD is small. Likewise over-erased bits may be hard to program resulting in under-programmed bits which are easy to erase. However not any under-erased bit is hard to program. In this embodiment, after performing programming the threshold voltage VT of the former under-erased bit is close to the average threshold voltage P0 or exceeds this value. Similarly not any over-programmed bit is hard to erase.

In case bits are extremely over-erased so that their threshold voltage VT is larger than a leakage threshold voltage PAEV the respective memory cells are conductive even if the reading potentials are not applied to these memory cells. Due to the large amount of holes, which are trapped in the charge trapping regions of these memory cells, a leakage current flows. Memory cells storing extremely over-erased bits are very power-consuming and the respective bit is usually hard to program. Due to this, the lifetime of this memory cells is reduced and the cells may fail after performing a few erasing cycles in series.

An embodiment comprising a so-called “programming after erasing” method enables to avoid the leakage current flow. This method comprises applying at least one programming pulse to the memory cell storing the over-erased bit so that the threshold voltage VT becomes larger than the leakage threshold voltage PAEV.

The following so-called “programming before erasing” method enables to avoid failure of memory cells storing bits that are rarely programmed and often re-erased. The over-erased bits are prepared for erasing in order to mitigate further threshold voltage decrease due to erasing.

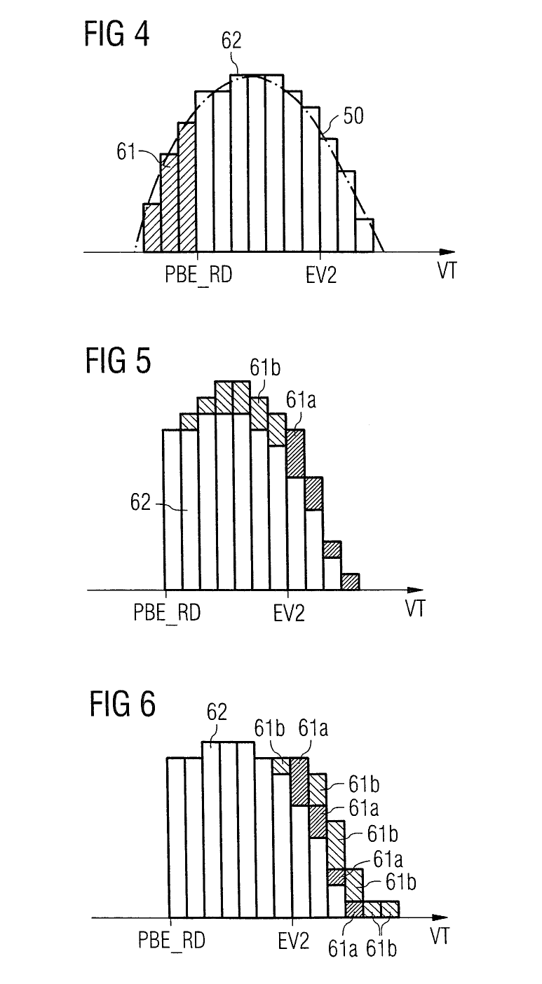

FIG. 4 shows a histogram of the erased bits over the threshold voltage VT according the distribution curve 51 shown in FIG. 3. The histogram comprises several bars each having a height and a width. The height of each bar indicates the number of bits represented by a threshold voltage VT that is within an interval that is indicated by the position on the VT-axis and the width of the bar. In order to clarify the following method the histogram includes only a few bars.

The over-erased bits are verified whether each threshold voltage VT representing one of the bits is less than a given first threshold voltage PBE_RD. The first threshold voltage PBE_RD is adjusted between the erase voltage EV and the leakage threshold voltage PAEV, particularly close to the leakage threshold voltage PAEV. Verifying the second bits 102 may be performed by applying the first threshold voltage PBE_RD on the gate and a certain voltage between the first and second doping area 201, 202 of each memory cell 100 and then detecting whether a current flows. If the current flows the threshold voltage VT is less than the first threshold voltage PBE_RD. The first bits 101 are verified applying the inverse voltage between the first and second doping area 201, 202.

The bits represented by a threshold voltage VT which is less than the first threshold voltage PBE_RD are assigned to a first group that is indicated by hatching in FIG. 4. The other bits 62 are assigned to a second group. Although the following description of the method preferably concerns the erased bits, the programmed bits are assigned also to the second group because they are represented by threshold voltages VT which are much larger than the first threshold voltage PBE_RD.

The threshold voltages VT of the bits 61 assigned to the first group are changed so that the threshold voltages VT get closer to the reading voltage RD or exceed the reading voltage RD. Changing is performed by applying one programming pulse, which is also called programming before erasing pulse or PBE pulse, to the memory cells which store the bits 61 assigned to the first group. It is also possible to apply more than one programming pulse to these memory cells 61. Alternative the applied voltage of the PBE pulse is larger than the applied voltage of the programming pulse.

FIG. 5 shows the histogram according to FIG. 4 after performing changing the threshold voltages VT. The threshold voltages VT representing the bits 61a, 61b that have been assigned to the first group are increased. The same number of PBE pulses, which is usually one, is applied to the memory cells in order to change the threshold voltages VT representing bits 61a, 61b assigned to the first group. However, the changing of the threshold voltages VT varies. The varied threshold voltages VT are indicated in FIG. 5 by hatching.

The above-described embodiment includes changing the threshold voltages VT which are below the leakage threshold voltage PAEV. Thus the leakage current flow is suppressed.

Based on the dependence of the changed threshold voltages, VT of the bits 61a, 61b is assigned to the first group and further programming before the erasing step is performed.

The threshold voltages VT representing the bits 61a, 61b assigned to the first group are verified to a given second threshold voltage EV2. This comparison enables to detect whether the bits are easy to erase or hard to erase. The bits 61a, represented by a threshold voltage VT, which are larger than the second threshold EV2, are assigned to the second group. These bits 61a are easy to program and therefore hard to erase. The bits 61b represented by a threshold voltage VT which is less than the second threshold EV2 remain assigned to the first group. These bits 61b are hard to program and easy to erase.

The threshold voltages VT of the bits 61b that are still assigned to the first group are changed during a second changing step. One PBE pulse is applied to the respective memory cells in order to increase to threshold voltages VT representing the bits 61b assigned to the first group. The second changing step may comprise applying more than one PBE pulse.

The second threshold voltage EV2 may be equal to the erase voltage EV. In this case the threshold voltages VT of the former over-erased bits becomes larger than the threshold voltages VT of the rest of the erased bits after performing a further changing step. Alternatively the second threshold voltage EV2 may be equal to the reading voltage RD. In order to change the threshold voltages VT of the former over-erased bits 61 these bits become programmed. The second threshold voltage EV2 may be larger, or less than, the erase voltage EV.

FIG. 6 shows the modified histogram, according to FIG. 5, after performing the second changing step. The threshold voltages VT representing the bits 61b assigned to the first group are further increased.

Due to the above described changes of the threshold voltages VT the following erasing step, in order to re-erase all formerly erased bits 61, 61a, 62, preferably does not result in threshold voltages VT being less than the leakage threshold voltage PAEV.

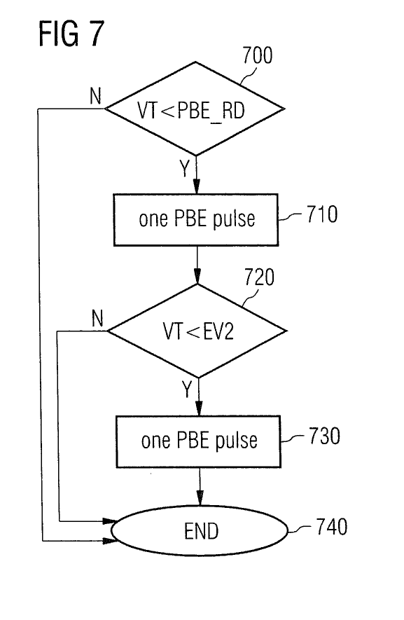

FIG. 7 summarizes an embodiment of the invention. FIG. 7 is a flow chart indicating the programming before erasing method concerning one of the bits stored in one of the memory cells. During the first step 700 the threshold voltage VT representing the bit is verified to the first threshold voltage PBE_RD. If the threshold voltage VT is less than the first threshold voltage PBE_RD, at least one PBE pulse is applied to the memory cell in order to increase the threshold voltage VT during the following changing step 710. If the threshold voltage VT is larger than the first threshold voltage PBE_RD the threshold voltage VT is not changed before erasing.

After performing the changing step 710 the threshold voltage VT is verified to the second threshold voltage EV2 during the verifying step 720. If the threshold voltage VT is less than the given second threshold EV2 a further PBE pulse is applied to this memory cell during the second changing step 730.

The erasing step is preferably performed to this bit after performing the above described programming before erasing method.

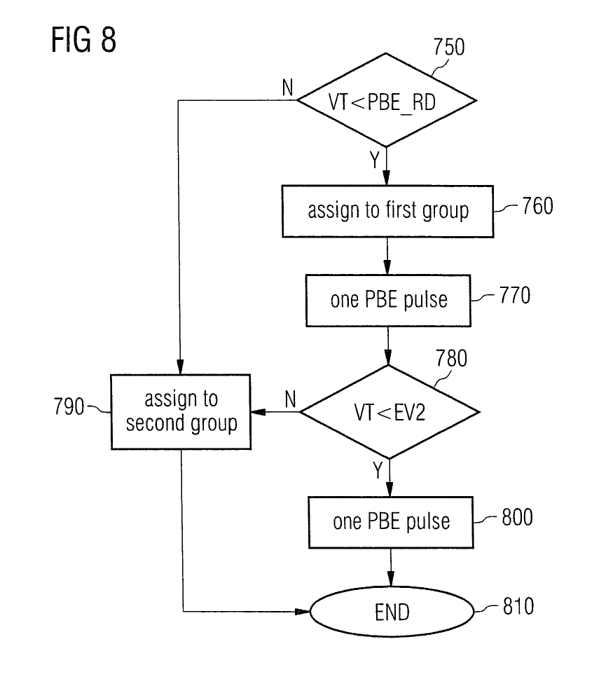

FIG. 8 shows a flow chart indicating yet another embodiment of the method that concerns a plurality of bits storing in a plurality of memory cells which may be assigned to an erasing sector. During the first step 750 each bit is verified to the first threshold voltage PBE_RD. If the threshold voltage VT is less than the first threshold voltage PBE_RD the bit is assigned to the first group during the following assigning step 760. Otherwise the bit is assigned to the second group during the following assigning step 790. One PBE pulse is applied to the memory cells which store bits assigned to the first group in order to increase the threshold voltages VT representing these bits. The threshold voltages representing the bits assigned to the second group are not changed.

After performing this changing step 770 the threshold voltages VT representing the bits assigned to the first group are verified to the second threshold voltage EV2 during step 780. If the threshold voltage VT is larger than the second threshold voltage EV2 the respective bit is assigned to the second group during the assigning step 790. If the threshold voltage VT is less than the second threshold voltage EV2 the respective bit remains assigned to the first group. During step 800 a further PBE pulse is applied to the memory cells storing the bits assigned to the first group in order to increase the threshold voltages VT representing these bits.

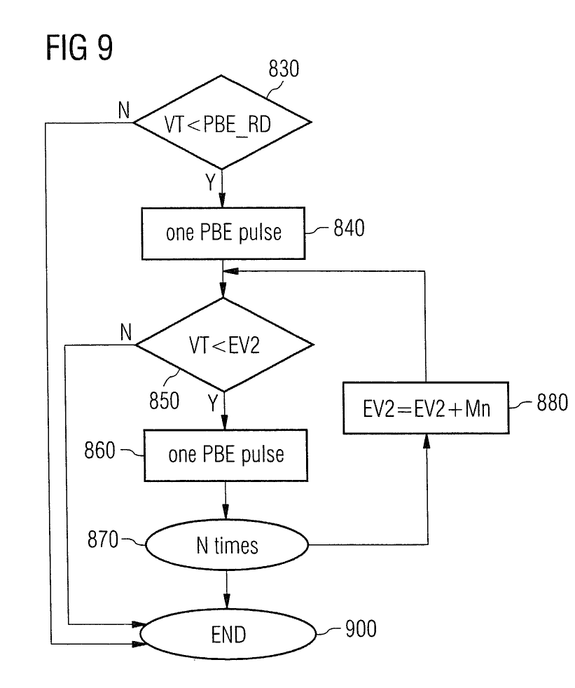

FIG. 9 shows a further embodiment of the inventive method. The flow chart shows the method concerning one bit.

During the first step 830 the threshold voltage VT representing the bit is verified to the first threshold voltage PBE_RD. If the threshold voltage VT is less than the first threshold voltage PBE_RD one programming pulse is applied to the memory cell in order to increase the threshold voltage VT as indicated in step 840. If the threshold voltage VT is larger than the first threshold voltage PBE_RD the threshold voltage VT is not changed before erasing.

During the second verifying step 850 the changed threshold voltage VT is verified to the second threshold voltage EV2. If the threshold voltage VT is less than the second threshold voltage EV2 one PBE pulse is applied to the memory cell in order to increase the threshold voltage VT as indicated in step 860.

The verifying and changing steps 850, 860 may be repeated several times wherein the second threshold EV2 is changed each time. The number of iteration, indicated as N in block 870, depends on the desired degree of tuning of the over-erased bits. Preferably the second threshold EV2 is increased stepwise as indicated in step 880. The increment, Mn, may be equal during each step 880 or may vary. It is also possible that the verifying and changing steps 850, 860 are repeated N times without changing the second threshold voltage EV2. In this case the threshold voltages VT of bits which are hard to program are changed more often than bits which are easy to program.

This embodiment enables stepwise increasing of the threshold voltage VT and stepwise tuning of the over-erased bits.

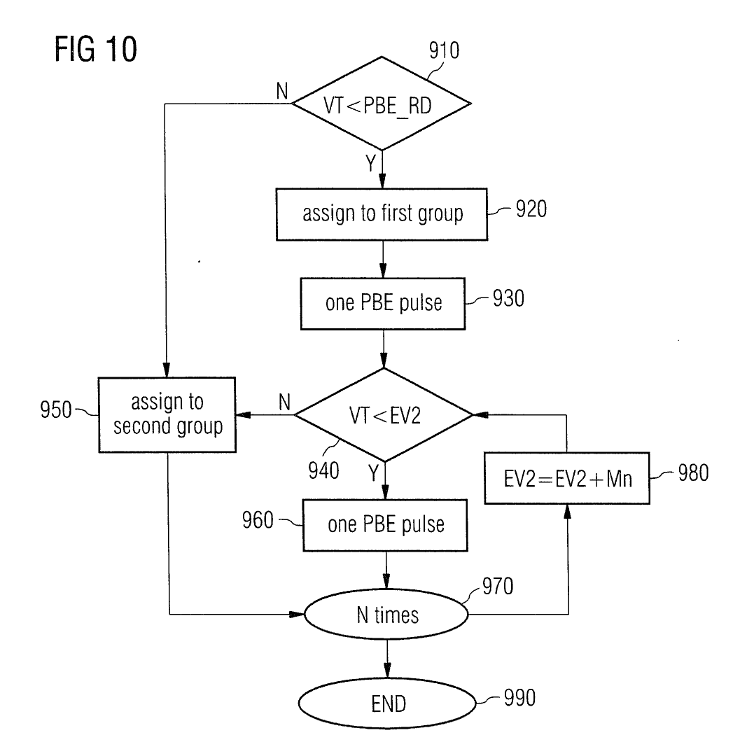

FIG. 10 shows yet another embodiment of the method, which concerns a plurality of bits. Each threshold voltage VT representing one of the bits is verified to the first threshold voltage PBE_RD during the first step 910. If the threshold voltage VT is less than the first threshold voltage PBE_RD the bit represented by this threshold voltage VT is assigned to the first group during the assigning step 920. Otherwise the bit is assigned to the second group during step 950.

During the first changing step 930 one PBE pulse is applied to the memory cells storing the bits assigned to the first group. Then the threshold voltage VT representing bits assigned to the first group is verified to the second threshold EV2 during step 940. If the threshold voltage VT is larger than the second threshold voltage EV2 the bits are assigned to the second group during the assigning step 950. Otherwise the bits remain assigned to the first group and a further PBE pulse is applied in order to increase the respective threshold voltages VT during the changing step 960.

The loop including the verifying step 940 and the changing step 960 may be repeated several times as indicated in FIG. 9.

The above describes programming before the erasing method may be used similarly in order to decrease the threshold voltages of over-programmed memory cells.

Assigning the bits each represented by its threshold voltage to the first or the second group is on par with assigning the respective threshold voltages to the first or second group.

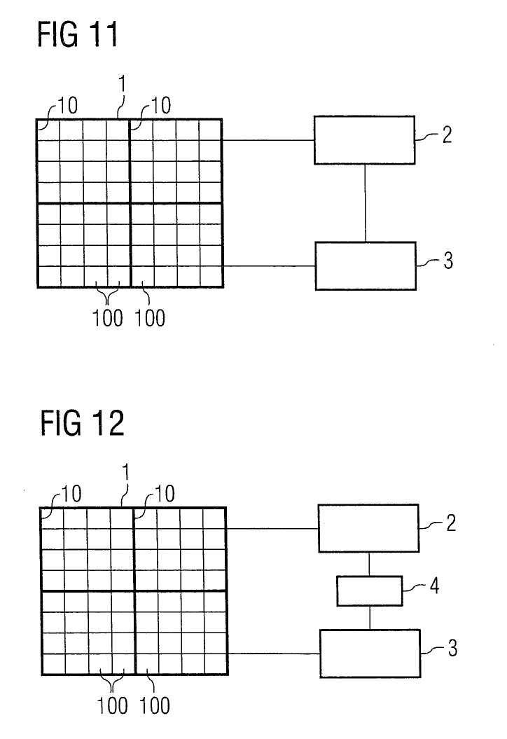

FIG. 11 shows an embodiment of a memory device that is operable to perform the above describe programming before erasing method.

The memory device comprises a memory cell array 1 including a plurality of memory cells 100 each assigned to one of the erasing sectors 10. Each memory cell 100 is operable to store at least one bit. In case of NROM memory cells each memory cell is operable to store a first and a second bit. Each stored bit is represented by one threshold voltage VT.

An access unit 3 is coupled to the memory cell array 1. The access unit 3 is operable to erase the bits stored in the memory cells 100 and to program the bits. The access unit is operable to provide erasing pulses, which are then applied to the memory cells 100 storing the bits to be erased. In case of erasing simultaneously the memory cells 100 assigned to an erasing sector 10 the bits to be erased may include programmed and erased bits. The access unit is further operable to provide programming pulses, which are applied to the memory cells storing the bit to be programmed in order to increase the threshold voltage VT representing the bit. The access unit 3 is further operable to apply PBE pulses in order to change the threshold voltage VT that the threshold voltage VT is closer to the reading voltage RD or that the stored bit is altered.

The memory device further comprises a verifying unit 2 coupled to the memory cell array 1 and to the access unit 3.

The identifying unit is operable to verify whether the threshold voltage VT is larger than a given threshold voltage. The threshold is variable in order to verify to the first or second threshold voltage PBE_RD, EV2, the latter being may be changeable in order to perform several iteration steps each including verifying and changing.

The access unit is operable to identify the bits represented by the threshold voltage VT being less than the given first threshold voltage PBE_RD and the respective memory cells and is operable change these threshold voltage VT. The access unit is operable to identify the bits represented by the threshold voltage VT have been changed during the prior changing step and being less than the given second threshold voltage PBE_RD and the respective memory cells and is operable to change these threshold voltages VT.

The memory device may comprise a counter coupled with the identifying unit and the access unit, which is operable to count the number of iterations of the verifying and the changing step.

FIG. 12 shows a memory device according to FIG. 11 further comprising an assigning unit 4 coupled between the verifying unit 2 and the access unit 3 which is operable to assign each of the bits to a first group if the representing threshold voltage is less than the given threshold voltage PBE_RD, EV2 or to a second group otherwise.

The access unit is operable to identify the bits assigned to the first group and the respective memory cells in order to change the respective threshold voltages VT.

Assigning the bits each represented by its threshold voltage to the first or the second group is on par with assigning the respective threshold voltages to the first or second group.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for restoring information stored in a memory cell that has a variable characteristic indicator of the stored information, wherein the variable characteristic indicator designates a first state if the variable characteristic indicator is below a reading threshold and the variable characteristic indicator designates a second state if the variable characteristic indicator is above the reading threshold, the method comprising:
verifying whether an absolute value of a first difference between the variable characteristic indicator and the reading threshold is larger than a given first threshold; and
changing the variable characteristic indicator when the absolute value of the first difference is larger than the given first threshold so that at least one of the absolute value of the first threshold is reduced or the stored state is altered.

2. The method in accordance with claim 1, further comprising:
verifying whether an absolute value of a second difference between the variable characteristic indicator changed during a previous changing step and the reading threshold is larger than a given second threshold; and
changing the variable characteristic indicator changed during the previous changing step when the absolute value of the second difference is larger than the given second threshold so that at least one of the absolute value of the second difference is reduced and the stored state is altered.

3. The method in accordance with claim 2, further comprising repeating changing the second threshold.

4. The method in accordance with claim 3, wherein changing the second threshold comprises reducing the second threshold.

5. The method in accordance with claim 1, wherein the variable characteristic indicator comprises a threshold voltage of the memory cell.

6. The method in accordance with claim 1, further comprising restoring the information after the verifying and changing steps.

7. The method in accordance with claim 1, wherein changing the variable characteristic indicator comprises applying at least one changing pulse to the memory cell.

8. A method to restore information stored in a plurality of memory cells, wherein the memory cell has a variable characteristic indicating the stored information, wherein the variable characteristic designates a first state if the variable characteristic is below a reading threshold and the variable characteristic designates a second state if the variable characteristic is above the reading threshold, the method comprising:
determining an absolute value of a first difference between the variable characteristic and the reading threshold;
assigning the variable characteristic to at least one of a first group and a second group when the absolute value of its first difference is larger than the given first threshold; and
changing the variable characteristics assigned to the first group so that at least one of the absolute value of its first difference is reduced and the stored state is altered when the absolute value of its first difference is less than or equal to the given first threshold.

9. The method in accordance with claim 8, further comprising:
determining an absolute value of a second difference between the variable characteristic assigned to the first group and the reading threshold;
assigning the variable characteristic assigned the first group to the second group when the absolute value of its second difference is less than the given second threshold; and
changing the variable characteristic assigned to the first group so that at least one of the absolute value of the second difference is reduced or the stored state is altered.

10. The method in accordance with claim 9, further comprising repeating the steps of verifying and changing.

11. The method in accordance with claim 10, wherein changing the second threshold comprises reducing the second threshold.

12. The method in accordance with claim 8, wherein the variable characteristic comprises a threshold voltage of the memory cell.

13. The method in accordance with claim 9, wherein the information is restored after performing the verifying and changing steps.

14. The method in accordance with claim 8 wherein changing the variable characteristic comprises applying at least one changing pulse to the memory cell.

15. A memory device comprising:
a memory cell array comprising a plurality of memory cells, wherein each memory cell stores information based upon a characteristic of the memory cell;
a verifying unit coupled to the memory cell array, wherein the verifying unit determines the difference between the characteristic and the reading threshold; and
an access unit coupled to the memory cell array and the verifying unit, wherein the access changes a verified characteristic so that the difference is reduced or that the stored state is altered, thereby producing a changed characteristic.

16. The memory device in accordance with claim 15 wherein the verifying unit further determines the difference between the changed characteristic and the reading threshold.

17. The memory device in accordance with claim 16, wherein the access unit further changes the changed characteristic so that the absolute value of the difference between the changed characteristic and the reading threshold is larger than a given second threshold.

18. The memory device in accordance with claim 17, wherein the given second threshold is variable.

19. The memory device in accordance with claim 15, wherein the characteristic comprises a threshold voltage of the memory cell.

20. The memory device in accordance with claim 15, wherein each memory cell stores at least two bits, wherein each bit is indicated by one characteristic.

21. The memory device in accordance with claim 15, wherein the access unit provides a change signal to the memory cell array, wherein the change signal comprises at least one changing pulse.

22. The memory device in accordance with claim 21, wherein the access unit provides a restoring signal to the memory cell array so that the same state is stored in each memory cell.

23. A memory device comprising:
a memory cell array comprising a plurality of memory cells, wherein each memory cell stores information, the information being indicated by a characteristic of the memory cell, wherein the characteristic designates a first state if the characteristic is below a reading threshold and the variable characteristic designates a second state if the characteristic is above the reading threshold;
a verifying unit coupled to the memory cell array, wherein the verifying unit determines whether the absolute value of a first difference between the characteristic and the reading threshold is larger than a given first threshold;
an assigning unit coupled to the verifying unit, wherein the assigning unit assigns a verified characteristic to a first group if the absolute value of its first difference is larger than the given first threshold or to a second group otherwise; and
an access unit coupled to the memory cell array and the assigning unit, wherein the access unit changes the characteristic assigned to the first group so that the absolute value of its first difference is reduced or that the stored state is altered.

24. The memory device in accordance with claim 23, wherein the verifying unit further verifies whether the absolute value of a second difference between the characteristic assigned to the first group and the reading threshold is larger than a given second threshold.

25. The memory device in accordance with claim 24, wherein the assigning unit further assigns the verified characteristic of the first group to the second group if the absolute value of its second difference is less than the given second threshold.

26. The memory device in accordance with claim 23, wherein the second threshold is variable.

27. The memory device in accordance with claim 23, wherein the characteristic comprises a threshold voltage of the memory cell.

28. The memory device in accordance with claim 23, wherein each memory cell stores at least two bits each indicated by one characteristic.

29. The memory device in accordance with claim 23, wherein the access unit provides a changing signal to the memory cell array, wherein the changing signal comprises at least one changing pulse.

30. The memory device in accordance with claim 23, wherein the access unit provides a restoring signal to the memory cell array so that the same state is stored in each memory cell.
